(19) United States
(12) Patent Application Publication
(10) Pub. No.: US 2007/0267942 A1
(43) Pub. Date: Nov. 22, 2007

(54) PIEZOELECTRIC FILM RESONATOR, RADIO-FREQUENCY FILTER USING THEM, AND RADIO-FREQUENCY MODULE USING THEM

(76) Inventors: Hisanori MATSUMOTO, Kokubunji (JP); Atsushi ISOBE, Kodaira (JP)

Correspondence Address: MILES & STOCKBRIDGE PC, 1751 PINNACLE DRIVE, SUITE 500, MCLEAN, VA, 22102-3833, US

(21) Appl. No.: 11/746,955

(22) Filed: May 10, 2007

(30) Foreign Application Priority Data
May 19, 2006 (JP) 2006-139882

(51) Int. Cl. H03H 9/25

(52) U.S. Cl. 310/313 A; 310/366

(57) ABSTRACT

A piezoelectric film resonator for a radio-frequency circuit according to an aspect of the present invention includes a substrate and a multilayer film provided on the substrate. The multilayer film has a stacked structure in which at least two piezoelectric layers and at least three electrode layers disposed with each of the piezoelectric layers therebetween are stacked. At least one of the electrode layers is an electrode layer for excitation. The electrode layer for excitation has a structure in which a plurality of unit patterns as elements of the electrode layer for excitation are disposed periodically along a direction substantially perpendicular to a stacked direction of the stacked structure.

### CLAIM OF PRIORITY

The present application claims priority from Japanese application JP 2006-139882 filed on May 19, 2006, the content of which is hereby incorporated by reference into this application.

### FIELD OF THE INVENTION

The present invention relates to a piezoelectric film resonator for use in radio-frequency circuits (hereafter referred to as “RF circuit”), a radio-frequency filter (hereafter referred to as “RF filter”) using them, and a radio-frequency module (hereafter referred to as “RF module”) using them.

### BACKGROUND OF THE INVENTION

As resonators and RF filters for use in RF circuits, surface acoustic wave devices (hereafter referred to as “SAW devices”) have been known (for example, see IEEE Transactions on Ultrasonics, Ferroelectics, and Frequency Control, vol. 42, no. 4, pp. 495-508, 1995).

On the other hand, as a resonator/filter technology applicable in a high frequency band, film bulk acoustic wave resonators (hereafter referred to as “FBAR”) have been known (for example, see 1994 IEEE International Frequency Control Symposium pp. 135-138).

Further, a technology in which an interdigital transducer electrode (hereafter referred to as “IDT”) is disposed on one surface of a piezoelectric substrate to excite Lamb waves (for example, see Japanese Patent Application Laid-Open Publication No. 2003-258596) and one in which an IDT is disposed on both surfaces of a piezoelectric substrate to excite Lamb waves (for example, see Japanese Patent Application Laid-Open Publication No. 2005-217818) have been known.

### SUMMARY OF THE INVENTION

It is assumed that in order to support radio communications at higher frequencies, a resonator or a filter operable at a frequency of several GHz or more is required. As filters for cellular phones, SAW devices have been used. However, those SAW devices have a problem that two to three GHz is a limit in supporting higher frequencies because acoustic waves generated by those SAW devices propagate at relatively low velocities, which will make it difficult to achieve more high frequency.

FBAR is a resonator/filter technology applicable in higher frequencies than SAW devices. However, the resonant frequency of FBAR is determined by the film thickness, so the thicknesses of the piezoelectric layer and the electrode layer must be controlled on the order of nanometers. This disadvantageously makes FBAR a highly difficult and high-cost manufacturing technology.

In the technologies in which an IDT is disposed on a surface(s) of a piezoelectric substrate to excite Lamb waves, properly selecting the relationship between the thickness of the piezoelectric substrate and the period of the electrode finger of the IDT allows Lamb waves to be excited at a higher propagation velocity than SAW. This allows the resonant frequency to easily be made higher. Further these technologies allow a resonator for supporting a relatively high frequency to be achieved at a low manufacturing cost. However, in these technologies, no method for achieving a resonator with a wide bandwidth has been disclosed.

Among basic figures of merit of a resonator is the relative bandwidth. The relative bandwidth of a resonator is defined as

100×(fa−fr)/fa

where fr is the resonant frequency of the resonator, and fa is the antiresonant frequency. With regard to a resonator using acoustic waves, the factor determines the relative bandwidth is the electromechanical transduction efficiency. In other words, as the efficiency with which inputted electric energy is transduced into elastic energy is increased, a resonator with a wide bandwidth can be achieved.

When an electrode such as IDT is used in a piezoelectric body to excite Lamb waves, the positional relation between the electrode and the piezoelectric body is deemed an important factor for determining the electromechanical transduction efficiency. However, with regard to related-art resonators that excite Lamb waves, such a factor has not sufficiently been discussed or examined. Therefore, neither resonator nor filter that uses a resonator for exciting Lamb waves so as to ensure a large relative bandwidth extending from several hundred MHz to ten and several GHz has been known.

### SUMMARY OF THE INVENTION

The present invention has been made in view of the above circumstance and provides a piezoelectric film resonator that has a large relative bandwidth over a wide frequency range, and a filter using the resonator.

A typical one of aspects of the invention disclosed in this application will briefly be described below.

A piezoelectric film resonator for a radio-frequency circuit according to an aspect of the present invention includes a substrate and a multilayer film provided on the substrate. The multilayer film has a stacked structure in which at least two piezoelectric layers and at least three electrode layers disposed with each of the piezoelectric layers therebetween are stacked. At least one of the electrode layers is an electrode layer for excitation. The electrode layer for excitation has a structure in which a plurality of unit patterns as elements of the electrode layer for excitation are disposed periodically along a direction substantially perpendicular to a stacked direction of the stacked structure.

The present invention allows a piezoelectric film resonator with a high electromechanical transduction efficiency and a large relative bandwidth to be provided.

### BRIEF DESCRIPTION OF THE DRAWINGS

Embodiments of the present invention will be described in detail with reference to the accompanying drawings, wherein:

FIG. 1 is a sectional view showing a piezoelectric film resonator according to an embodiment of the present invention;

FIG. 2 is a top view showing the piezoelectric film resonator according to the first embodiment of the present invention;

FIG. 3 is a perspective view showing the piezoelectric film resonator according to the first embodiment of the present invention;

FIG. 4 is a flowchart showing an example of the process of manufacturing a multilayer film in the piezoelectric film resonator according to the first embodiment of the present invention;

FIG. 5 is a schematic sectional view showing the aspect of an electric field distribution in the piezoelectric film resonator according to the first embodiment of the present invention;

FIG. 6 is a schematic view showing a model of the piezoelectric film resonator according to the present invention used in a simulation by the finite element method;

FIGS. 7A to 7D are diagrams showing an example of wave modes of the piezoelectric film resonator according to the present invention obtained by the simulation using the finite element method;

FIGS. 8A and 8B are graphs showing an example of the propagation velocity (FIG. 8A) and resonant frequency (FIG. 8B) for each of the wave modes of the piezoelectric film resonator according to the present invention obtained by the simulation using the finite element method;

FIG. 9 is a graph showing an example of the relative bandwidth for each of the wave modes of the piezoelectric film resonator according to the present invention obtained by the simulation using the finite element method;

FIGS. 10A and 10B are graphs showing another example of the propagation velocity (FIG. 10A) and resonant frequency (FIG. 10B) for each of the wave modes of the piezoelectric film resonator according to the present invention obtained by the simulation using the finite element method;

FIG. 11 is a graph showing another example of the relative bandwidth for each of the wave modes of the piezoelectric film resonator according to the present invention obtained by the simulation using the finite element method;

FIGS. 12A and 12B are a top view (FIG. 12A) and a schematic sectional view (FIG. 12B) of the piezoelectric film resonator according to the present invention, created as a prototype;

FIGS. 13A and 13A are graphs showing an X-ray diffraction pattern obtained by measuring the crystal orientation of the piezoelectric film resonator according to the present invention, created as a prototype;

FIGS. 14A and 14B are graphs showing an example of actual measured values of the impedance characteristic of the piezoelectric film resonator according to the present invention, created as a prototype;

FIGS. 15A and 15B are graphs showing an example of actual measured values of the impedance characteristic of the piezoelectric film resonator according to the present invention, created as a prototype;

FIG. 16 is a sectional view showing a piezoelectric film resonator including an acoustic isolator layer, according to a second embodiment of the present invention;

FIG. 17 is a sectional view showing a piezoelectric film resonator including a Bragg reflection layer, according to the second embodiment of the present invention;

FIG. 18 is a sectional view showing a piezoelectric film resonator including dielectric layers, according to a third embodiment of the present invention;

FIG. 19 is a sectional view showing a piezoelectric film resonator including a sacrifice layer, according to a fourth embodiment of the present invention;

FIG. 20 is a top view showing a piezoelectric film resonator including reflectors, according to a fifth embodiment of the present invention;

FIG. 21 is a sectional view showing a piezoelectric film resonator according to a sixth embodiment of the present invention;

FIG. 22 is a sectional view showing a piezoelectric film resonator according to a seventh embodiment of the present invention;

FIG. 23 is a sectional view showing a piezoelectric film resonator according to an eighth embodiment of the present invention;

FIG. 24 is a circuit block diagram including a front end part in a cellular phone adopting an embodiment of the present invention;

FIG. 25 is a circuit block diagram of a transmit filter and a receive filter in the front end part shown in FIG. 24, the transmit and receive filters both including an arrangement of a plurality of piezoelectric film resonators according to any one of embodiments of the present invention;

FIG. 26 is a schematic perspective view showing a transmit filter including piezoelectric film resonators according to embodiments of the present invention, manufactured on a common substrate; and

FIG. 27 is a schematic sectional view showing an aspect of an electric field distribution in a resonating element of a related-art piezoelectric film resonator.

### DETAILED DESCRIPTION OF THE PREFERRED EMBODIMENTS

Embodiments of the present invention will be described below in detail with reference to the accompanying drawings.

### First Embodiment

First, an embodiment that adopts an IDT as an electrode for excitation will be described.

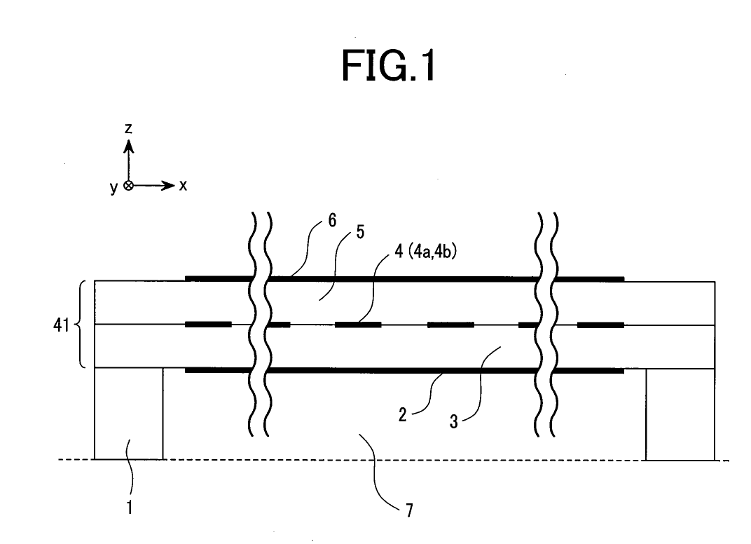

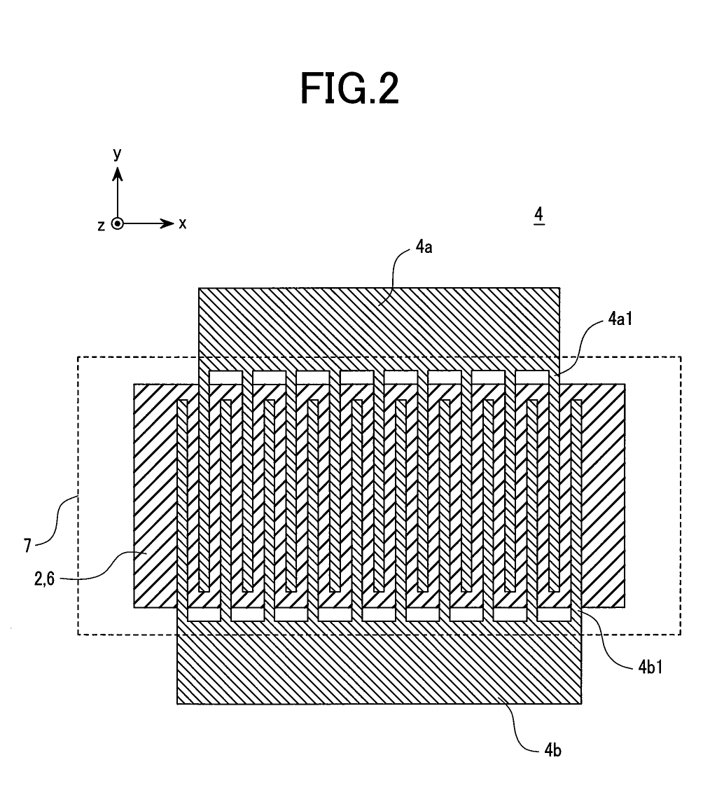

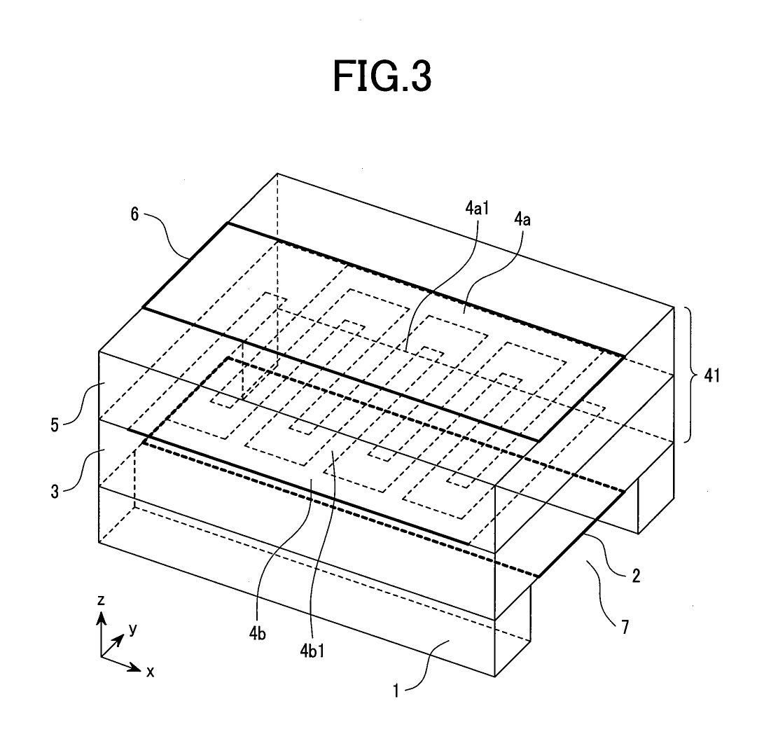

FIG. 1 is a sectional view showing a piezoelectric film resonator according to a first embodiment of the present invention. FIGS. 2 and 3 are a top view and a perspective view, respectively, of the piezoelectric film resonator according to this embodiment. In these drawings, the directions in parallel to a plane of a substrate (or piezoelectric layer) are assumed as the x direction (or longitudinal direction) and y direction (or width direction); the direction in parallel to a normal line to the plane of the substrate (or piezoelectric layer) as the z direction (or height direction).

The piezoelectric film resonator according to this embodiment includes a substrate and a multilayer film disposed on the substrate. The multilayer film has a stacked structure in which two piezoelectric layers and three electrode layers are stacked in the z direction with the piezoelectric layers interposed between the electrode layers. At least one of the electrode layers is an electrode layer for excitation. In the electrode layer for excitation, a plurality of unit patterns as elements of the electrode are disposed periodically in the x direction. A preferable example of the electrode for excitation is an IDT whose electrode fingers, that is, unit patterns forming pairs are disposed periodically in the x direction by alternation. At least one of the piezoelectric layers has a polarization direction of the z direction. Detailed description will be made below.

As shown in FIG. 1, the piezoelectric film resonator includes a multilayer film 41 disposed on the substrate 1 and a cavity 7 formed directly below the multilayer film 41. The multilayer film 41 has a stacked structure in which electrode layers, piezoelectric layers, and the like are stacked in the z direction, more specifically, a stacked structure in which a bottom electrode layer 2, a bottom piezoelectric layer 3, an IDT 4, a top piezoelectric layer 5, and a top electrode layer 6 are stacked on the substrate 1. The IDT 4 is an electrode layer for excitation including a pair of electrode fingers (4a, 4b). A high frequency voltage whose polarity is inverted periodically is applied to the pair of electrode fingers (4a, 4b) via a pair of feeding terminals (not shown). Each electrode finger has a plurality of rectangular unit patterns disposed periodically in the x direction of the multilayer film 41. As shown in FIGS. 2 and 3, each unit pattern 4a1 and each unit pattern 4b1 take the shape of a substantially identical rectangle and are disposed symmetrically in parallel to a plane of the substrate. Further a plurality of unit patterns of the electrode finger 4a and a plurality of unit patterns of the electrode finger 4b are disposed at substantially equal intervals in the x direction. The period or interval of the unit patterns of one electrode finger may be slightly different from the period or interval of the unit patterns of the other electrode finger, depending on the positions of the unit patterns in the x direction. Those are preferably substantially identical to each other as a whole. Similarly, the shape of the unit patterns of the electrode finger 4a may be slightly different from that of the unit patterns of the electrode finger 4b, depending on the positions of the unit patterns in x and y directions. Those are preferably substantially identical to each other as a whole.

The number of the unit patterns of an electrode finger in FIG. 2 is different from that of the unit patterns of the corresponding electrode finger in FIG. 3. This is because the unit patterns in FIG. 3 are zoomed in to facilitate the understanding of the structure of the piezoelectric film resonator. As a matter of course, those are identical to each other in practice.

The bottom electrode layer 2 and the top electrode layer 6 are disposed so as to overlap the electrode fingers 4a and 4b of the IDT 4 in the z direction. In other words, as shown in FIG. 2, the top and bottom electrode layers are each formed as an individual rectangular plane that has lengths in the x and y directions approximately opposed to the entire unit patterns of the electrode fingers 4a and 4b of the IDT 4. The bottom electrode layer 2 and the top electrode layer 6 each have a polarization direction of the z direction. The top and bottom electrode layers may each include a plurality of planes.

The IDT 4 excites Lamb waves that are to propagate through the multilayer film 41. The bottom electrode layer 2 and the top electrode layer 6 are floating electrodes for controlling (direct) the direction of an electric field in order to increase the electromechanical transduction efficiency. The floating electrodes are electrodes for giving a reference potential to the IDT 4 and may be disposed as ground electrodes. Since the IDT 4 includes the plurality of electrode fingers disposed periodically in the x direction, when each electrode finger excites Lamb waves that are to propagate in the x direction, acoustic energy held by the excited Lamb waves is converted into electrical energy and absorbed by adjacent electrode fingers. This prevents the energy held by the Lamb waves from leaking out of the electrodes during propagation of the Lamb waves, allowing a resonator with a high Q factor to be obtained.

The cavity 7 serves to prevent the acoustic energy of the Lam waves excited by the IDT 4 from leaking in the substrate direction. In this embodiment, as shown in FIG. 2, the cavity 7 is disposed in the entire region directly below the bottom electrode layer 2, the IDT 4, and the top electrode layer 6. However, the cavity 7 is not limited to this embodiment. For example, the cavity 7 may be formed so as to be smaller than the region directly below the bottom electrode layer 2, the IDT 4, and the top electrode layer 6 or may have a shorter width than the directly below region.

The cavity 7 can be formed from the back surface of the substrate 1 using a typical technique in the semiconductor manufacturing process, such as dry etching or wet etching. The cavity 7 can also be formed by previously forming the cavity 7 on the surface of the substrate 1 and then filling the cavity with a sacrifice layer, by forming the multilayer film 41 and then making a through hole at an edge of the multilayer film 41, and by removing the sacrifice layer via the through hole by dry etching or wet etching. The through hole for removing the sacrifice layer may be formed from the back surface of the substrate.

At least one of the bottom piezoelectric layer 3 and the top piezoelectric layer 5 preferably has a polarization direction in parallel to a normal line to a plane of the piezoelectric layer. As a result, the orientations of electric fields generated between the IDT 4 and the bottom electrode layer 2 and the top electrode layer 6 becomes in parallel to the polarization direction of the bottom piezoelectric layer 3 and the top piezoelectric layer 5. This allows the multilayer film 41 to excite Lamb waves more efficiently.

With regard to the dimensions of the piezoelectric film resonator according to this embodiment, the ratio h/λ₀ of the height h of the multilayer film 41 to the period λ₀ of the electrode fingers of the IDT 4 is preferably 0.05 or more and 10 or less. At this time, the thicknesses of the bottom piezoelectric layer 2 and the top piezoelectric layer 5 are both preferably 100 nanometers or more and 50 micrometers or less. The thickness of the bottom piezoelectric layer 2 and that of the top piezoelectric layer 5 is preferably matched, but may be different from each other in a wider design.

The bottom piezoelectric layer 3 and the top piezoelectric layer 5 are each made of a piezoelectric material mainly made of either aluminum nitride (AlN) or zinc oxide (ZnO). Alternatively the bottom piezoelectric layer 3 and the top piezoelectric layer 5 may be made of different materials. The bottom piezoelectric layer 3 and the top piezoelectric layer 5 may be each formed on an underlayer made of silicon dioxide, silicon nitride, alumina, tantalum oxide, titanium oxide, or the like. The bottom piezoelectric layer 3 and the top piezoelectric layer 5 can be formed by a technique such as sputtering or chemical vapor deposition (hereafter referred to as “CVD”).

The bottom electrode layer 2 and the top electrode layer 6 are each preferably made of a material mainly made of any one of aluminum (Al), molybdenum (Mo), and tungsten (W), or may be made of a material mainly made of an alternative such as gold (Au), platinum (Pt), silver (Ag), copper (Cu), titanium (Ti), chrome (Cr), ruthenium (Ru), vanadium (V), niobium (Nb), tantalum (Ta), rhodium (Rh), iridium (Ir), zirconium (Zr), hafnium (Hf), or palladium (Pd). Alternatively the bottom electrode layer 2 and the top electrode layer 6 may have a multilayer structure in which two or more of the abovementioned conductive materials are used. Alternatively the bottom electrode layer 2 and the top electrode layer 6 may be each formed on an underlayer made of silicon dioxide, silicon nitride, alumina, tantalum oxide, titanium oxide, AlN, ZnO, or the like. The bottom electrode layer 2 and the top electrode layer 6 can be formed by a technique such as sputtering, CVD, vacuum deposition, or liquid deposition.

The IDT 4 is preferably made of a conductive material mainly made of any one of Al, Mo, and W, or may be made of a material mainly made of an alternative such as Au, Pt, Ag, Cu, Ti, Cr, Ru, V, Nb, Ta, Rh, Ir, Zr, Hf, or Pd. Alternatively the IDT 4 may have a multilayer structure in which two or more of the abovementioned conductive materials are used. Alternatively the IDT 4 may be formed on an underlayer made of silicon dioxide, silicon nitride, alumina, tantalum oxide, titanium oxide, AlN, ZnO, or the like. The IDT 4 can be formed by a technique such as sputtering, CVD, vacuum deposition, or liquid deposition.

As shown in FIGS. 2 and 3, the bottom electrode layer 2 and the top electrode layer 6 are disposed so as to overlap the electrode fingers 4a and 4b of the IDT 4. The pair of electrode fingers 4a and 4b are each coupled to a radio-frequency circuit via a feeding terminal (not shown). The cavity 7 is formed in the region overlapped by the electrode fingers 4a and 4b of the IDT 4, the bottom electrode layer 2, and the top electrode layer 6. In FIG. 2, the cavity 7 is formed in the entire region overlapped by the electrode fingers 4a and 4b of the IDT 4, the bottom electrode layer 2, and the top electrode layer 6. However, any one of the electrode fingers 4a, 4b of the IDT 4, the bottom electrode layer 2, and the top electrode layer 6 may be disposed so as to extend out from the region where the cavity 7 exists, without being limited to this embodiment. Applying an alternate voltage between the electrode fingers 4a and 4b of the IDT 4 allows Lamb waves that are to propagate through the multilayer film 41 to be excited.

The piezoelectric film resonator according to this embodiment can be manufactured by a general technique in a semiconductor manufacturing process.

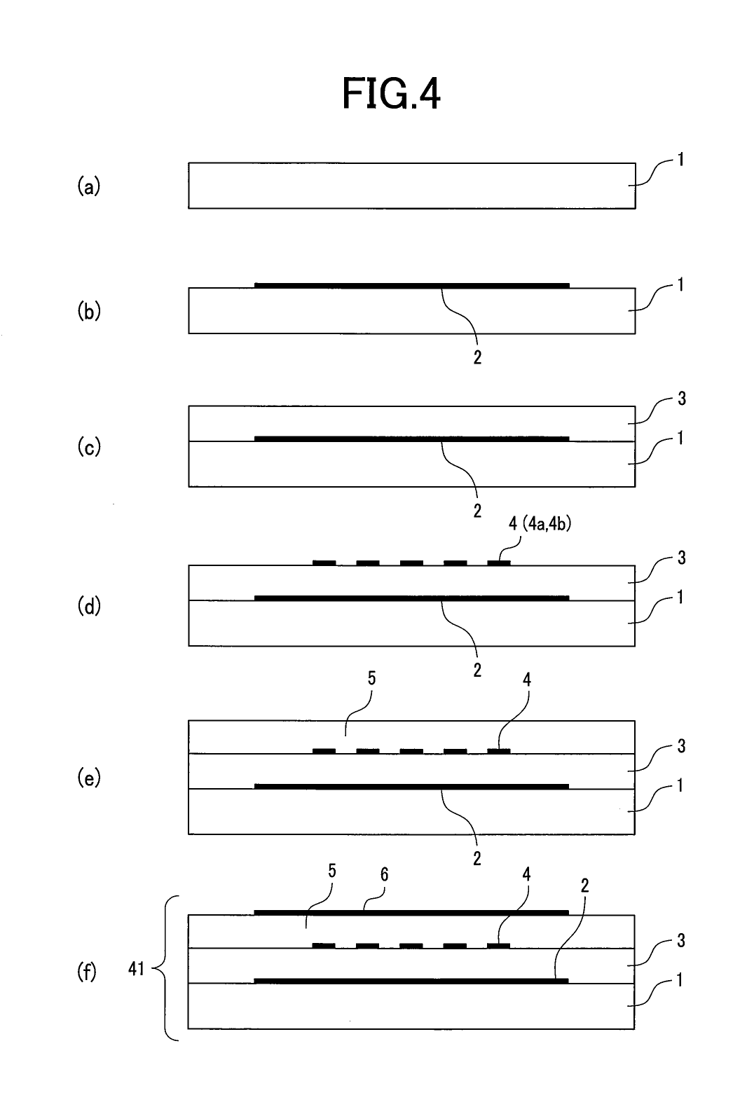

FIG. 4 shows an example of the process of manufacturing the piezoelectric film resonator according to this embodiment using a thin film forming technique. The manufacturing process will be described below referring to FIG. 4.

First, on the substrate 1 (see FIG. 4A), the bottom electrode layer 2 is formed and patterned (see FIG. 4B). Then the bottom piezoelectric layer 3 is formed on the bottom electrode 2 (see FIG. 4C). Then the IDT 4 having the electrode fingers 4a, 4b is formed and patterned on the bottom piezoelectric layer 3 (see FIG. 4D). Then the top piezoelectric layer 5 is formed on the IDT 4 (see FIG. 4E). Then the top electrode layer 6 is formed and patterned on the top piezoelectric layer 5 (see FIG. 4F). Then the cavity is formed in the region directly below the multilayer film, for example, from the back surface of the substrate, to obtain the piezoelectric film resonator according to this embodiment.

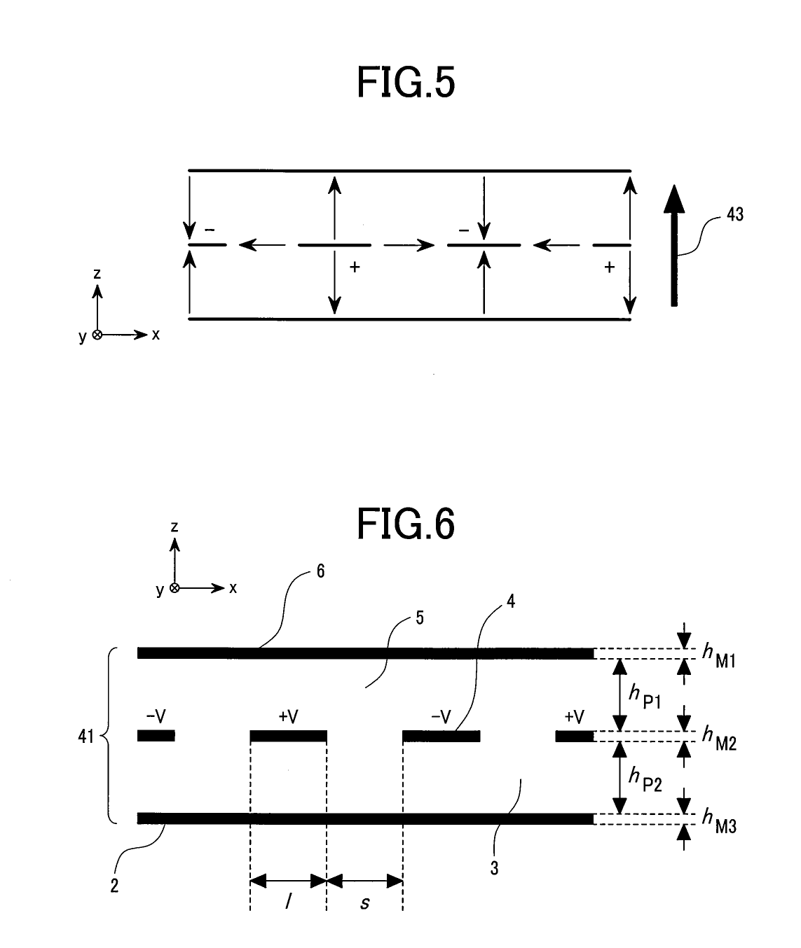

Now the action and advantage of the piezoelectric film resonator according to this embodiment will be described with reference to FIG. 5.

The top and bottom piezoelectric layers according to this embodiment both have a polarization direction of the z direction. The orientations of the electric fields generated between the bottom and top electrode layers, that is, electric field vectors are inverted in each of the bottom and top electrode layers. This allows only antisymmetric mode to be selectively excited.

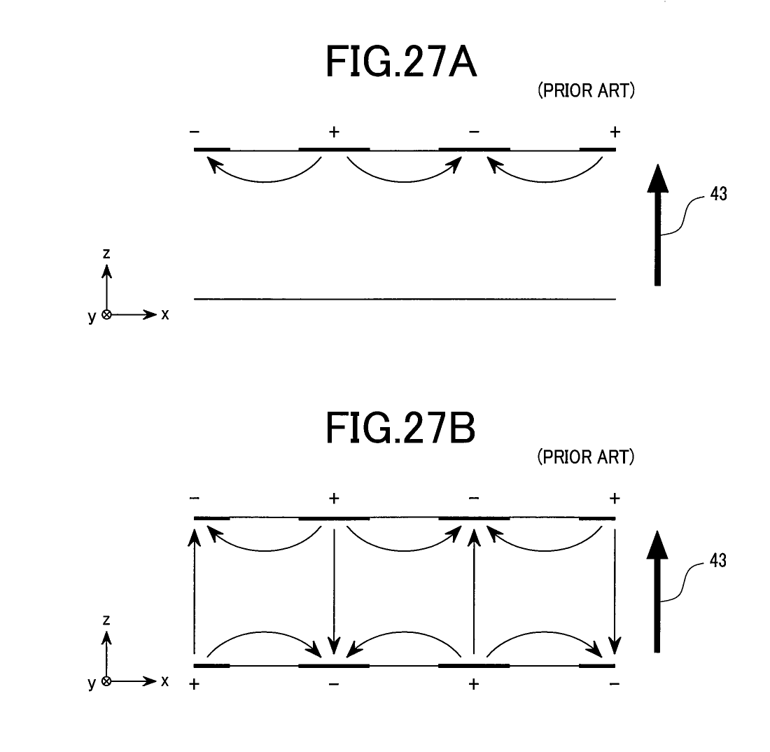

FIG. 5 is a schematic sectional view showing the aspect of an electric field distribution in the piezoelectric film resonator according to this embodiment. For comparison, schematic sectional views showing the aspects of electric field distributions in the resonating elements described in Japanese Patent Application Laid-Open Publication No. 2003-258596 and Japanese Patent Application Laid-Open Publication No. 2005-217818 are shown in FIGS. 27A and 27B, respectively. In these drawings, the thin arrows represent the principal electric field vectors and the thick arrows 43 represent the polarization direction of the piezoelectric layer.

### In other words, in FIG. 5 and FIGS. 27A and 27B, the piezoelectric layer has the polarization direction of the z direction.

In FIG. 5, the excitation efficiency is good because the orientations of the electric fields and the polarization directions of the piezoelectric layers are matched. Further, in FIG. 5, the top and bottom electrode layers both have the polarization direction of the z direction, and the vectors of the electric fields are inverted in each of the top and bottom piezoelectric layers. Thus, only the antisymmetric mode can selectively be excited. This is advantageous in reducing unnecessary modes that cause spurious mode.

On the other hand, in the method disclosed in Japanese Patent Application Laid-Open Publication No. 2003-258596, as shown in FIG. 27A, the excitation efficiency is bad because the orientations of the electric fields are different from the polarization directions of the piezoelectric layers. In the method disclosed in Japanese Patent Application Laid-Open Publication No. 2005-217818, as shown in FIG. 27B, the excitation efficiency is good because the orientations of the electric fields and the polarization directions of the piezoelectric layers are matched. However, since both symmetric mode and antisymmetric mode are excited, spurious mode is likely to occur.

As described above, this embodiment allows the electric field vectors to be put in parallel to the polarization directions of the bottom and top piezoelectric layers, thereby exciting the multilayer film more efficiently. This makes it possible to obtain a piezoelectric film resonator that has a large relative bandwidth in a high frequency band.

In order to examine the piezoelectric film resonator according to this embodiment, a simulation was performed using the finite element method.

FIG. 6 is a schematic view of a simulated piezoelectric film resonator model. In FIG. 6, the thicknesses of the top electrode layer 6, the IDT 4, and the bottom electrode layer 2 are defined as h_{M1}, h_{M2}, and h_{M3}, respectively. The thicknesses of the top piezoelectric layer 5 and the bottom piezoelectric layer 3 are defined as h_{P1} and h_{P2}, respectively. The width of the electrode fingers and the interval between the electrode fingers of the IDT 4 are defined as l and s, respectively. l and s here are each assumed to be 2 micrometers, and h_{M2} to be 0. Therefore, the period λ₀ of the IDT 4=2l+2s=8 micrometers, and the thickness h of the multilayer film 41=h_{P1}+h_{P2}+h_{M1}+h_{M3}. Here, it is assumed that the bottom and top piezoelectric layers are made of AlN, and the bottom and top electrode layers and IDT are made of Mo.

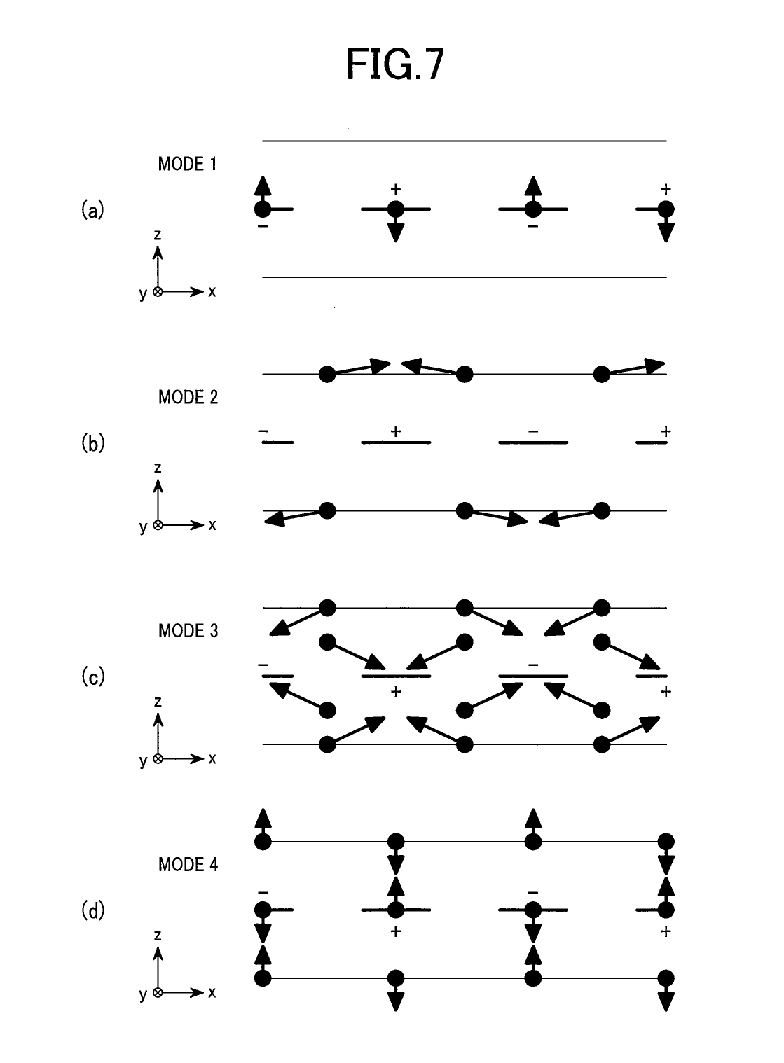

FIG. 7 schematically shows four typical modes (hereafter referred to as “mode 1,” “mode 2,” “mode 3,” and “mode 4” in descending order) among the wave modes obtained by the simulation. In the schematic view of each wave mode, the base point of each vector represents the maximum of mechanical displacement, and the direction of each vector represents the direction of mechanical displacement. The modes 1 to 4 are all antisymmetric modes in which waves are generated antisymmetrically relative to the center plane of the multilayer film 41. All wave modes other than the ones shown in FIG. 7 obtained by the simulation were also antisymmetric modes. In other words, the piezoelectric film resonator according to this embodiment basically has a characteristic of selectively exciting only antisymmetric mode.

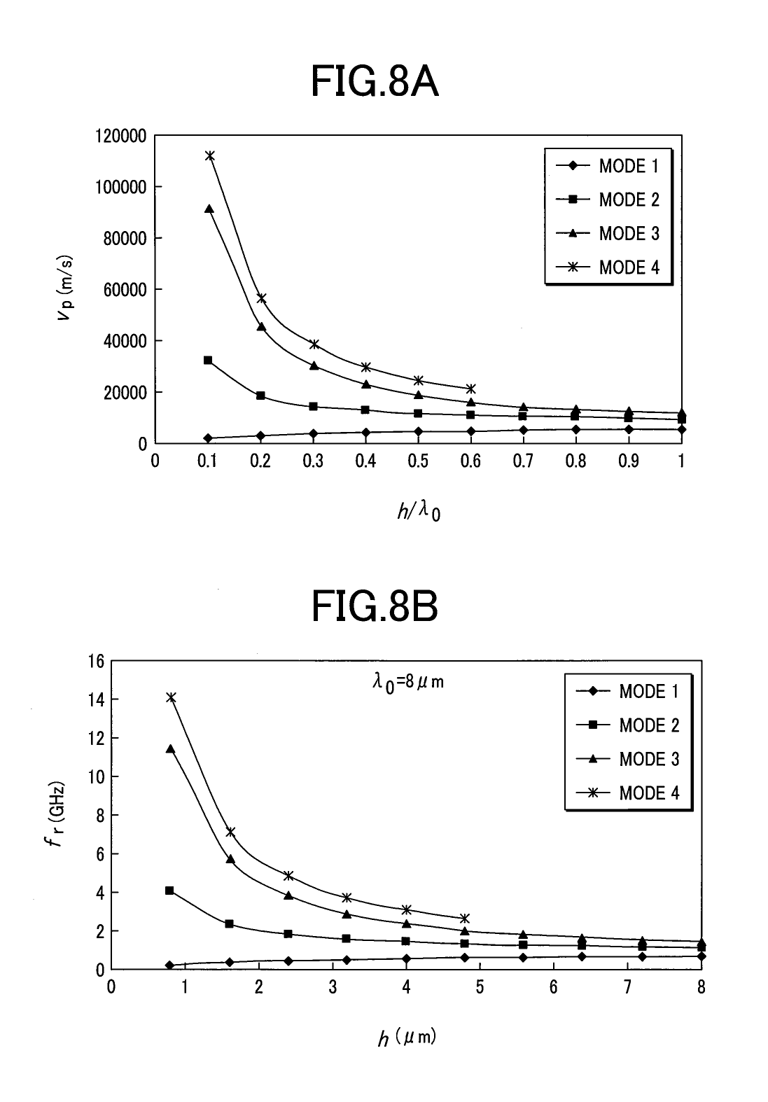

FIGS. 8A and 8b show examples of the propagation velocity (FIG. 8A) and the resonant frequency (FIG. 8b) for each of the modes 1 to 4 obtained by the simulation. Here, assuming that h_{M1}=h_{M3}=0, the simulation was performed while changing h/λ₀ from 0.1 to 1. Specifically, h was changed from 0.8 micrometers to 8 micrometers (provided that h_{P1}=h_{P2}).

Note that, in FIG. 8A, the characteristic of the mode 4 was calculated only when h/λ₀ is in the range of 0.1 to 0.6, thereby providing no further data. The same goes for FIG. 8B.

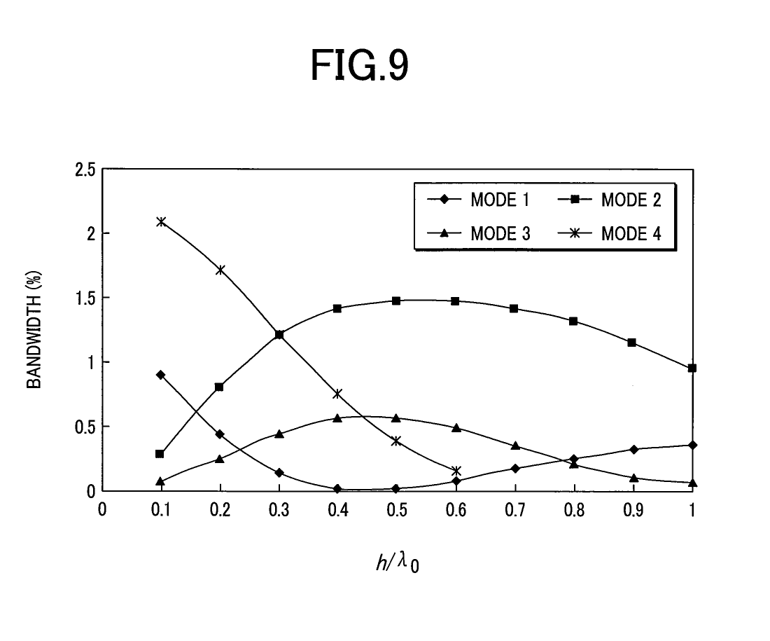

FIG. 9 shows the simulation results of the relative bandwidth of each mode corresponding to the simulations shown in FIG. 8A and FIG. 8B. For mode 1, when h/λ₀=0.1, the relative bandwidth is 0.90, which is the maximum, and the Lamb wave propagation velocity is 1670 m/s (resonant frequency: 0.209 GHz). For mode 2, when h/λ₀=0.5, the relative bandwidth is 1.47, which is the maximum, and the Lamb wave propagation velocity is 11446 m/s (resonant frequency: 1.431 GHz). For mode 3, when h/λ₀=0.5, the relative bandwidth is 0.57, which is the maximum, and the Lamb wave propagation velocity is 18893 m/s (resonant frequency: 2.362 GHz). For mode 4, when h/λ₀=0.5, the relative bandwidth is 2.09, which is the maximum, and the Lamb wave propagation velocity is 111912 m/s (resonant frequency: 13.989 GHz). In this simulation, it is assumed that the period λ₀ of the IDT 4 is 8 micrometers. However, as a matter of course, setting up this value properly allows the point where the relative bandwidth of each mode is the maximum to match the desired resonant frequency.

The simulation results described above show that, with regard to the piezoelectric film resonator according to this embodiment, properly selecting the thickness h of the multilayer film 41, the period λ₀ of the IDT 4, and the type of wave mode allows a resonator in a wide range of several hundred MHz to ten and several GHz to be achieved.

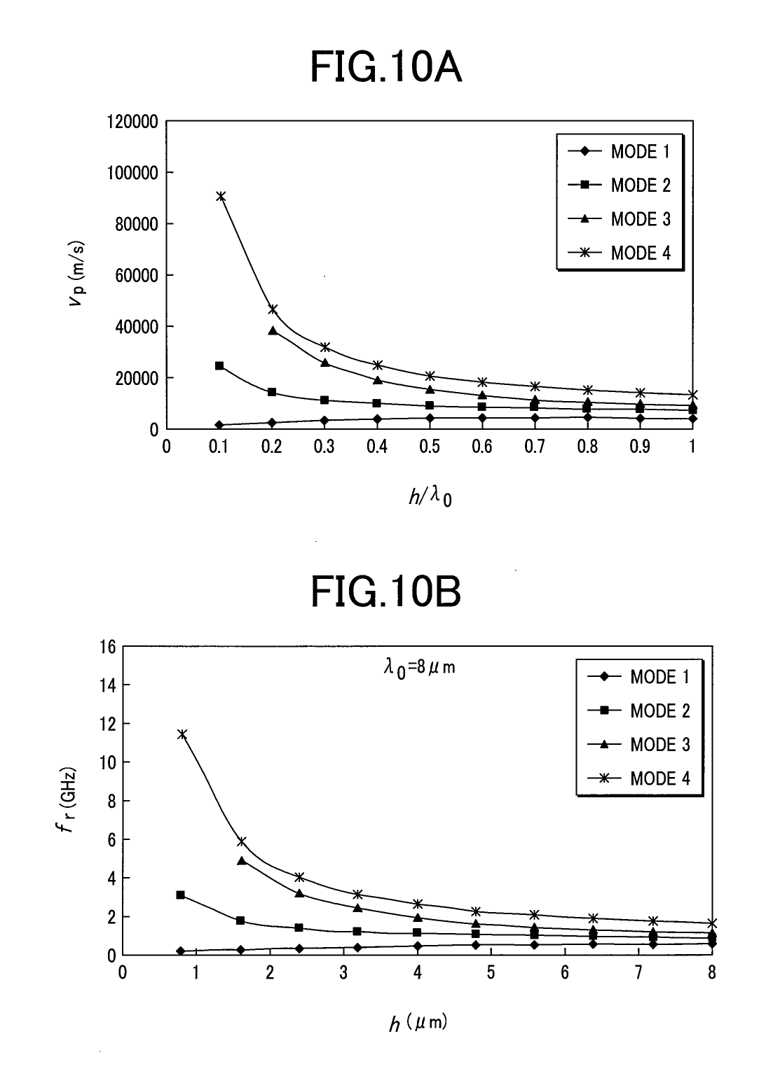

FIGS. 10A and 10B show another example of the propagation velocity (FIG. 10A) and the resonant frequency (FIG. 10B) for each of the modes 1 to 4 obtained by the simulation. Here, assuming that h_{M1}=h_{M3} and h_{P1}=h_{P2} and h_{M1}/h_{P1}=0.2, the simulation was performed while changing h/λ₀ from 0.1 to 1. Specifically, h was changed from 0.8 micrometers to 8 micrometers. Note that, in FIG. 10A, the characteristic of the mode 3 was calculated only when h/λ₀ is in the range of 0.2 to 1, thereby providing no data for h/λ₀=0.1. The same goes for FIG. 10B.

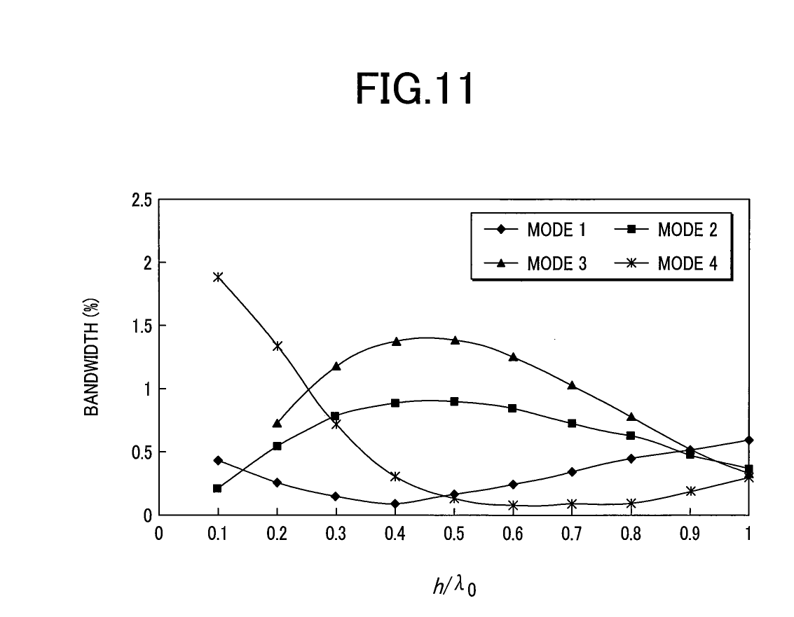

FIG. 11 shows the simulation results of the relative bandwidth of each mode corresponding to the simulation shown in FIGS. 10A and 10B. When FIGS. 10A and 10B are compared with FIGS. 8A and 8B, it is understood that the propagation velocity and resonant frequency are reduced as a whole because the respective thicknesses of the bottom electrode layer 2 and the top electrode layer 6 are taken into account.

When FIG. 11 is compared with FIG. 9, it is understood that the relative bandwidth has been changed upon the effect of mass loading of the bottom electrode layer 2 and the top electrode layer 6. A particularly remarkable effect is that the relative bandwidth of the mode 2 has been reduced, while the relative bandwidth of the mode 3 has been increased.

In order to examine the basic performance of the piezoelectric film resonator according to this embodiment, a device was actually created as a prototype to measure the electric property thereof.

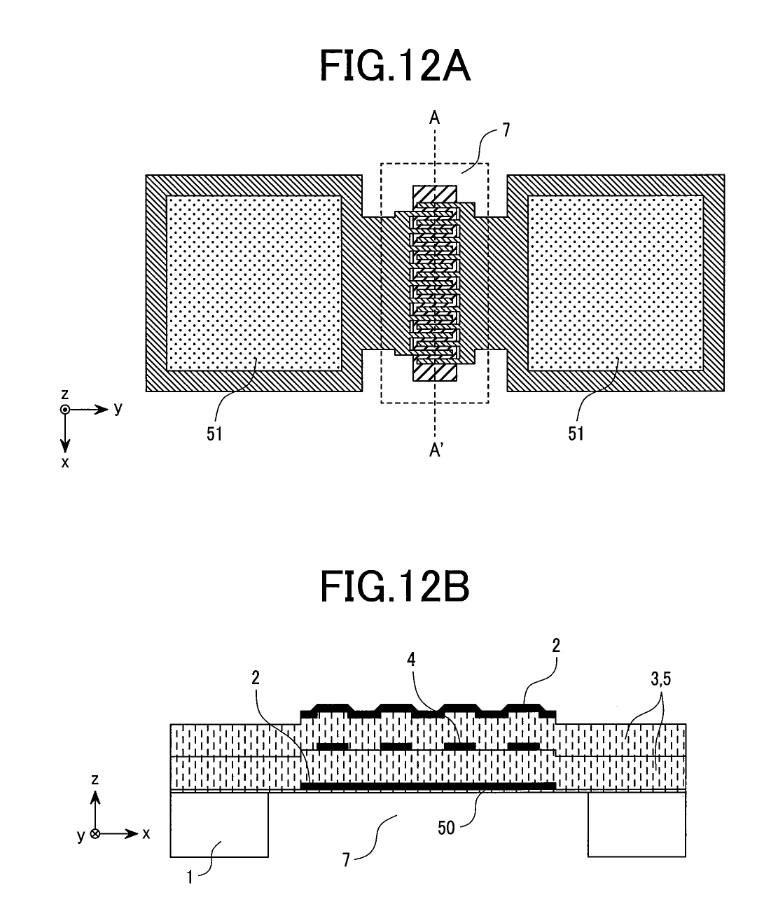

FIGS. 12A and 12A show schematic views of the piezoelectric film resonator created as a prototype. FIG. 12A is a top view of the piezoelectric film resonator, and FIG. 12B is a sectional view taken along line A-A′ of FIG. 12A. The top electrode layer 6, the top piezoelectric layer 5, the IDT 4, the bottom piezoelectric layer 3, and the bottom electrode layer 2 are 200 nanometers, 1 micrometer, 200 nanometers, 1 micrometer, and 200 nanometers, respectively, in film thickness. Placed below the bottom of the bottom electrode layer 2 is an underlayer 50 with a film thickness of approximately 30 nanometers. Mo is used as the top electrode layer 6, the IDT 4, and the bottom electrode layer 2. AlN is used as the top piezoelectric layer 5 and the bottom piezoelectric layer 3. An Si (100) wafer is used as the substrate 1. The cavity 7 is formed from the back surface of the substrate by dry etching. A reference numeral 50 represents an underlayer that is an extremely thin layer for acting as a stopper layer when the bottom electrode layer 2 is formed by dry etching process. A reference numeral 51 represents a pad electrode (feeding terminal) to be coupled to a radio-frequency circuit.

In FIG. 12B, due to steps formed by patterning the bottom electrode layer 2 and the IDT 4, a projection(s) is formed on each of the bottom piezoelectric layer 3, the top piezoelectric layer 5, and the top electrode layer 6. However, subjecting the bottom piezoelectric layer 3 and the top piezoelectric layer 5 to planarization allows a piezoelectric film resonator having a section with no step to be achieved. Such planarization can be performed using a technique such as mechanical polishing, chemical mechanical polishing, gas cluster ion beam, or ion milling.

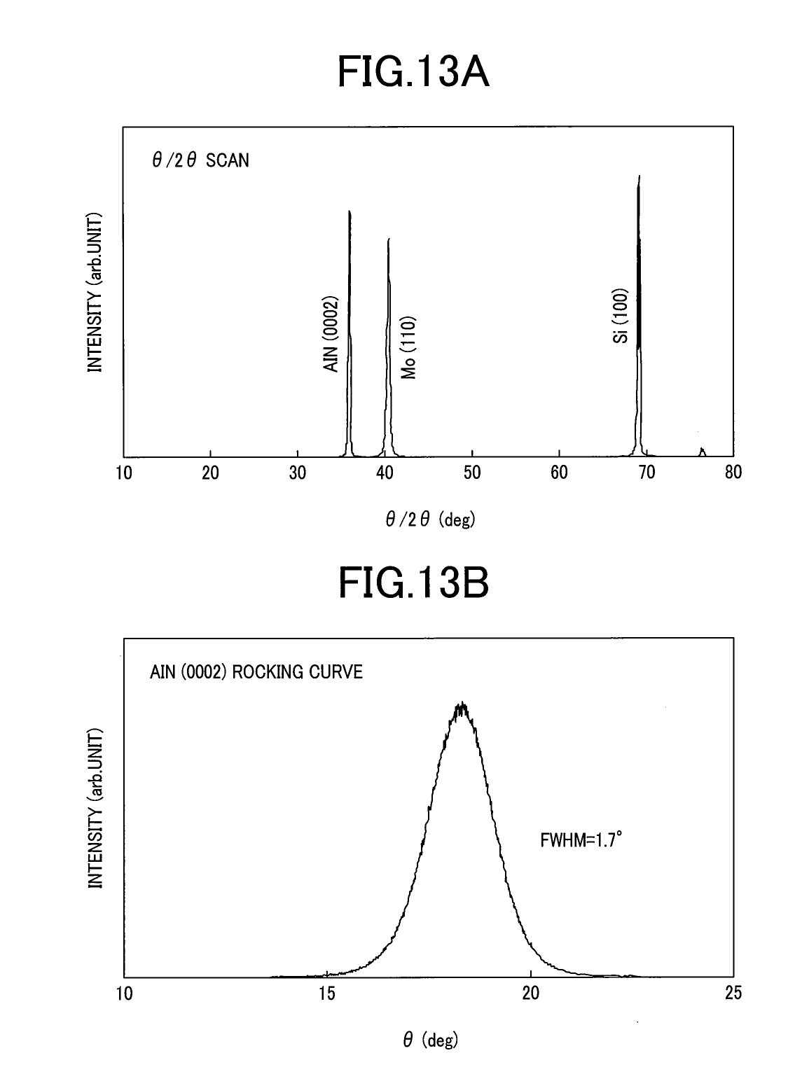

FIGS. 13A and 13B show the results obtained by measuring the crystal orientation of the film of the piezoelectric film resonator created as a prototype using the X-ray diffraction method. FIGS. 13A and 13B show a rocking curve of θ/2θ scan and AlN (0002), respectively. From this data, it is understood that AlN forming the top piezoelectric layer 5 and the bottom piezoelectric layer 3 is a single oriented film having, as the polarization direction, the direction perpendicular to a normal line to the film. At this time, the full width of half maximum of the rocking curve is 1.7 degrees.

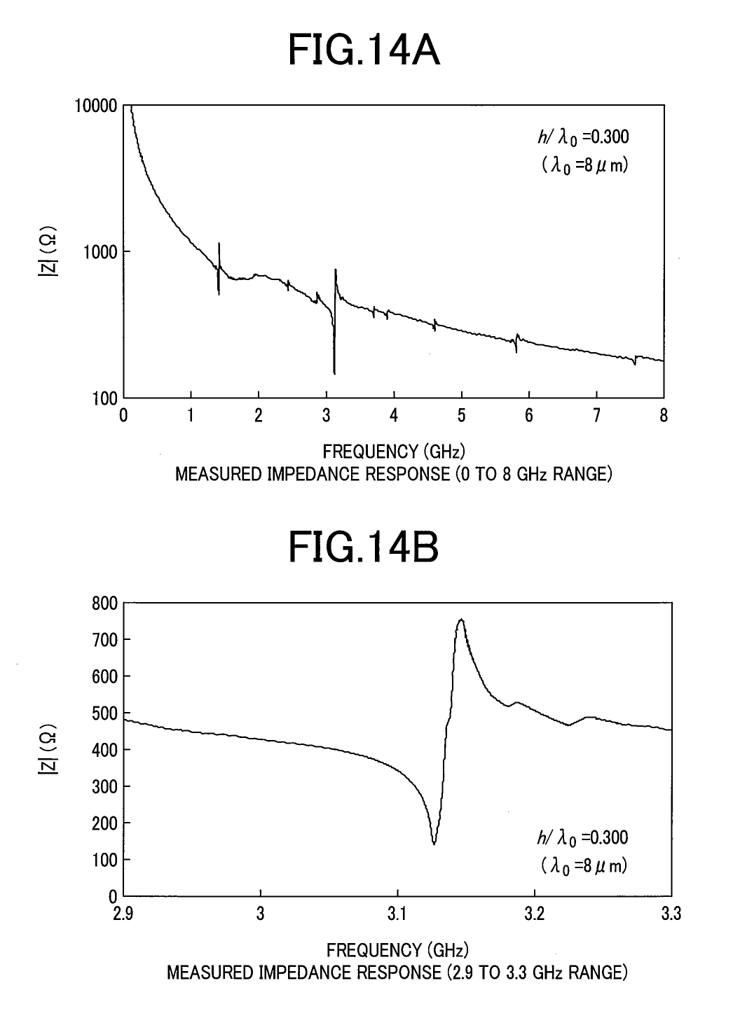

FIGS. 14A and 14B show the actual measured values of the impedance characteristic of the piezoelectric film resonator created as a prototype (0 to 8 GHz in FIG. 14A and 2.9 to 3.3 GHz in FIG. 14B). Here, h/λ₀ is 0.3. From FIGS. 14A and 14B, it is understood that there is a mode having a large relative bandwidth near 3.1 GHz. From a comparison with the simulation results, it is presumed that this is mode 3.

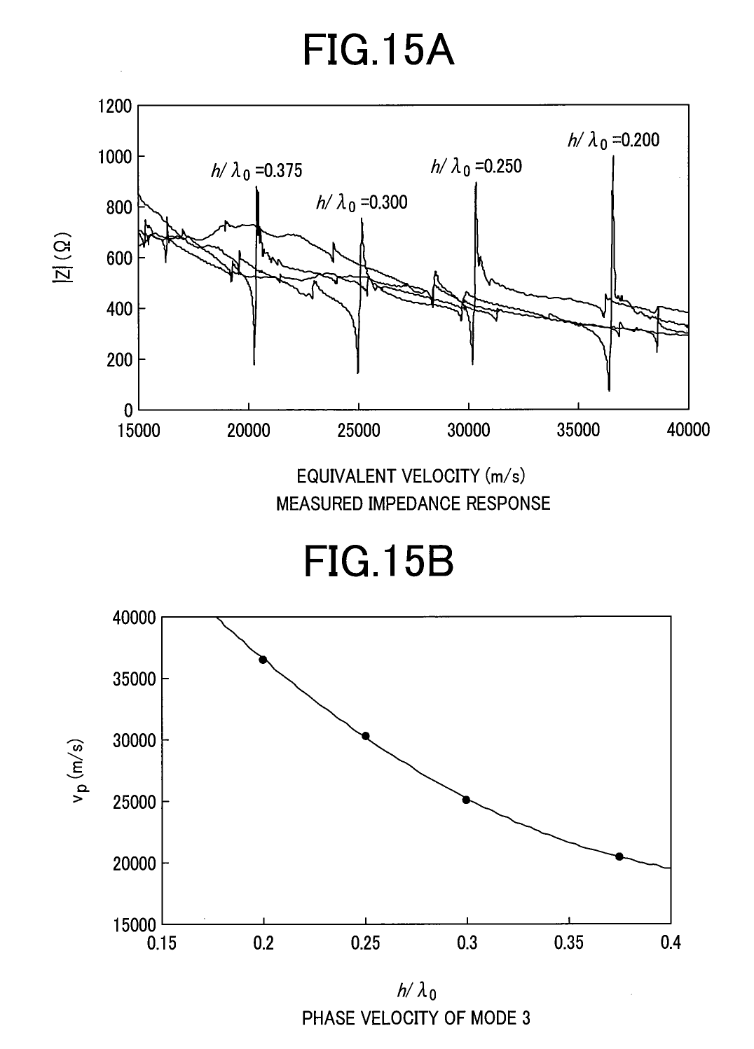

FIGS. 15A and 15B show the actual measured values of the impedance characteristic of the piezoelectric film resonator created as a prototype, as well as the differences in the impedance characteristic of the mode 3 among h/λ₀=0.200, h/λ₀=0.250, h/λ₀=0.300, and h/λ₀=0.375. From FIGS. 15A and 15B, it is understood that the propagation velocity of the mode 3 continuously changes depending on h/λ₀ and well matches the simulation results.

As described above, according to this embodiment, properly selecting the thickness h of the multilayer film 41, the period λ₀ of the IDT 4, and the type of wave mode allows the achievement of a piezoelectric film resonator that demonstrates an excellent characteristic in a wide range of several hundred MHz to ten and several GHz.

### Second Embodiment

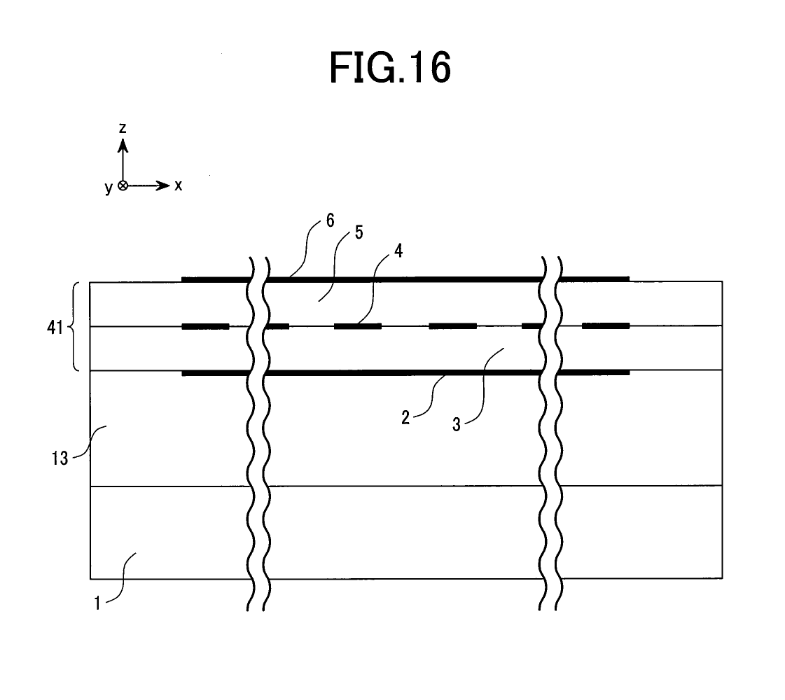

FIG. 16 is a sectional view showing a piezoelectric film resonator according a second embodiment of the invention. In FIG. 16, as with the first embodiment, the multilayer film 41 includes the bottom electrode layer 2, the bottom piezoelectric layer 3, the IDT 4, the top piezoelectric layer 5, and the top electric layer 6. However, in this embodiment, the acoustic isolator layer 13, instead of the cavity 7, is formed on the substrate 1. The multilayer film 41 is formed on the acoustic isolator layer 13.

The acoustic isolator layer 13 is formed in order to prevent acoustic energy generated by exciting the multilayer film 41 from being applied to the substrate 1. For example, the acoustic isolator layer 13 is a Bragg reflector layer formed by periodically stacking two or more layers with different acoustic impedances. In such a Bragg reflector layer, a layer with a high impedance is preferably made of W or Mo, and a layer with a low impedance is preferably made of Al or SiO₂.

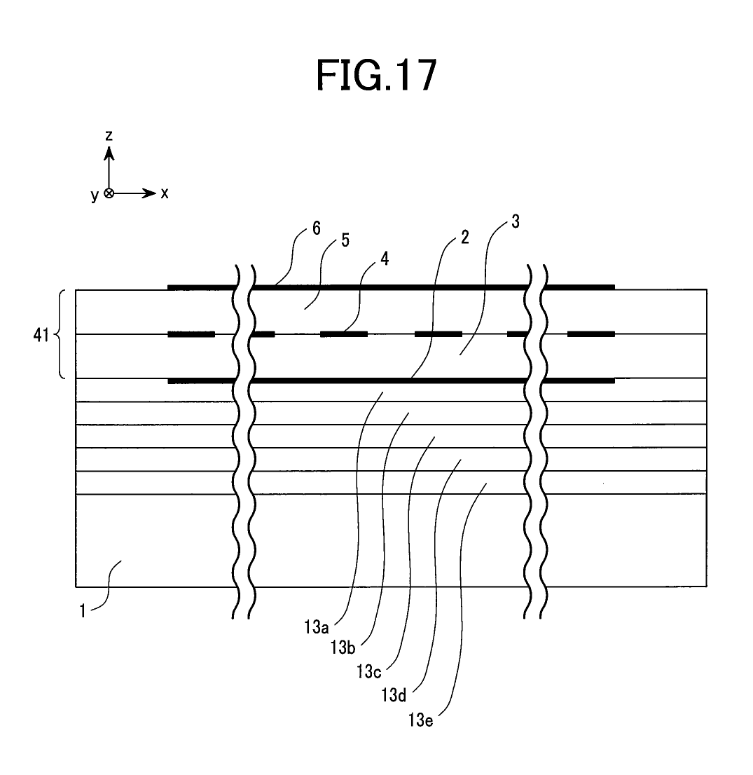

FIG. 17 shows a more detailed configuration example of the piezoelectric film resonator including the acoustic isolator layer and is a sectional view showing the piezoelectric film resonator in which a Bragg reflection layer is used as the acoustic isolator layer. The acoustic isolator layer 13 includes a plurality of layers 13a to 13e. A first layer 13a, a third 13c, and a fifth layer 13e are made of a material with a low impedance, such as Al or SiO₂, and a second layer 13b and a fourth layer 13d are made of a material with a high impedance, such as W or Mo. The film thicknesses of the first to fifth layers 13a to 13e are adjusted so as to match one-fourth of the wavelength of acoustic waves that propagate in the substrate direction (−z direction). Here the wavelength of acoustic waves that propagate in the substrate direction can be determined uniquely by the density of the material, elastic constant, and resonant frequency.

In the piezoelectric film resonator shown in FIG. 17, acoustic waves generated by exciting the multilayer film 41 propagate through the Bragg reflector layer in the depth direction. When the acoustic waves incident upon the boundary surface between a low impedance layer and a high impedance layer, a part of the acoustic waves is reflected and another part thereof is transmitted through the boundary surface and propagates. As the difference in acoustic impedance between adjacent layers is larger, the reflectivity of the acoustic waves becomes higher. Further, since the film thicknesses of the first to fifth layers 13a to 13e match one-fourth of the wavelength of the acoustic waves, the acoustic waves reflected from each such boundary surface strengthen one another and are returned to the multilayer film 41. Thus, the Bragg reflector layer allows the piezoelectric film resonator to achieve an energy trapping structure.

While the Bragg reflector layer includes five layers in FIG. 17, the optimal number of layers varies depending to the required reflectivity, material constant of each layer, or the like. One Bragg reflector layer is not necessarily made of two types of materials and may be made of three or more types of materials. Further, in order to provide an etch stopper layer, a buffer layer, or the like, an extremely thin layer may be inserted between the layers with a thickness of one-fourth of the wavelength. Furthermore, as with the first embodiment, an underlayer may be inserted between the acoustic isolator layer 13 and bottom electrode layer 2.

According to this embodiment, properly selecting the thickness h of the multilayer film 41, the configuration of the Bragg reflector layer, the period λ₀ of the IDT 4, and the type of wave mode allows the achievement of a piezoelectric film resonator that demonstrates an excellent characteristic in a wide range of several hundred MHz to ten and several GHz.

### Third Embodiment

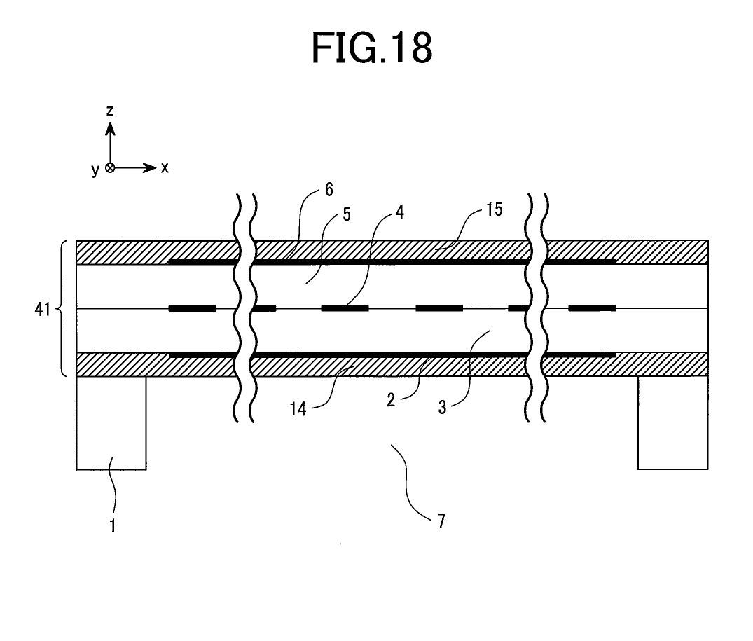

FIG. 18 is a sectional view showing a piezoelectric film resonator according a third embodiment of the invention. In FIG. 18, the multilayer film 41 includes the bottom electrode layer 2, the bottom piezoelectric layer 3, the IDT 4, the top piezoelectric layer 5, the top electric layer 6, a first dielectric layer 15 disposed on the top electrode layer 6, and a second dielectric layer 14 disposed below the bottom electrode layer 2. The first dielectric layer 15 and the second dielectric layer 14 perform temperature compensation, passivation, or the like, and are preferably made of a material such as silicon dioxide, silicon nitride, alumina, tantalum oxide, titanium oxide, or the like.

According to this embodiment, properly selecting the thickness h of the multilayer film 41, the configuration of the dielectric layer, the period λ₀ of the IDT 4, and the type of wave mode allows the achievement of a piezoelectric film resonator that demonstrates an excellent characteristic in a wide range of several hundred MHz to ten and several GHz.

### Fourth Embodiment

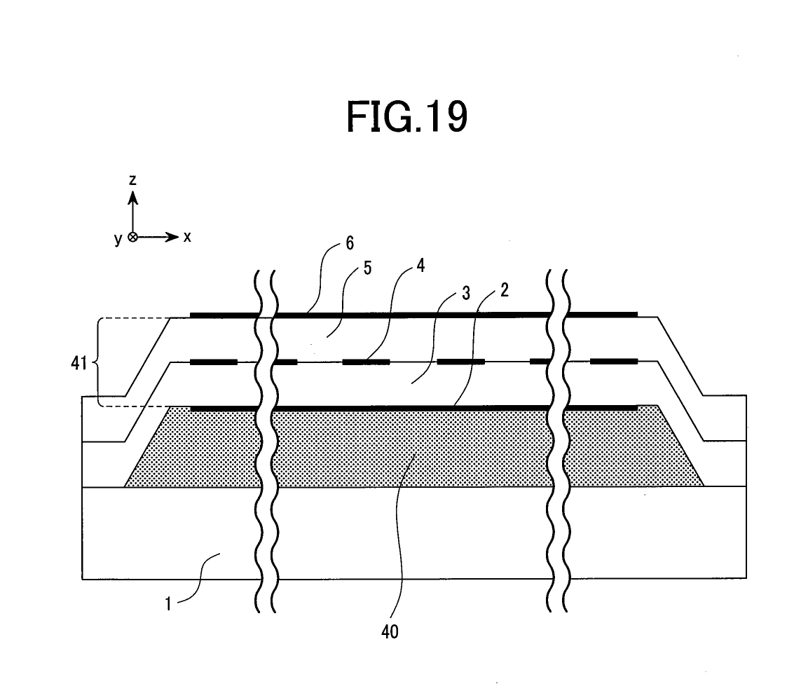

FIG. 19 is a sectional view showing a piezoelectric film resonator according a fourth embodiment of the invention. In FIG. 19, the multilayer film 41 including the bottom electrode layer 2, the bottom piezoelectric layer 3, the IDT 4, the top piezoelectric layer 5, and the top electric layer 6 is formed on a sacrifice layer 40 disposed on the substrate 1. At the final stage of the process of manufacturing the piezoelectric film resonator, the sacrifice layer 40 is eliminated via a through hole formed from an edge of the multilayer film 41 or a through hole formed from the back surface of the substrate by dry etching, wet etching, or the like. However, if the piezoelectric film resonator achieves required performance even though the sacrifice layer 40 is eliminated, the sacrifice layer 40 may not be eliminated.

According to this embodiment, properly selecting the thickness h of the multilayer film 41, the configuration of the sacrifice layer, the period λ₀ of the IDT 4, and the type of wave mode allows the achievement of a piezoelectric film resonator that demonstrates an excellent characteristic in a wide range of several hundred MHz to ten and several GHz.

### Fifth Embodiment

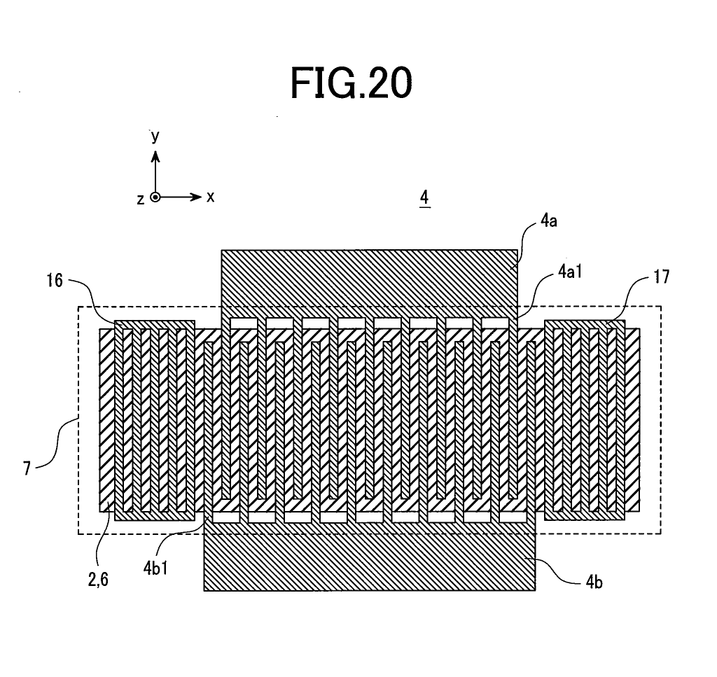

FIG. 20 is a top view showing a piezoelectric film resonator according a fifth embodiment of the invention. A first reflector 16 and a second reflector 17 are disposed at both edges of the IDT 4 (4a, 4b). The first reflector 16 and second reflector 17 serve to prevent Lam waves excited by the IDT 4 (4a, 4b) from leaking in the x direction. Since the Lamb waves propagating outwardly of the IDT 4 (4a, 4b) are again returned inwardly of the IDT 4 (4a, 4b) by the first reflector 16 and second reflector 17, a piezoelectric film resonator with a high Q factor can be achieved. While the line widths of the first reflector 16 and the second reflector 17 are basically equal to those of the IDT 4 (4a, 4b), the line widths of the first reflector 16 and the second reflector 17 and those of the IDT 4 (4a, 4b) may be different from each other in a wider design. The first reflector 16 and the second reflector 17 can be made of a material such as Al, Mo, W, Au, Pt, Ag, Cu, Ti, Cr, Ru, V, Nb, Ta, Rh, Ir, Zr, Hf, or Pd.

According to this embodiment, properly selecting the thickness h of the multilayer film 41, the configuration of the right and left reflectors, the period λ₀ of the IDT 4, and the type of wave mode allows the achievement of a piezoelectric film resonator that demonstrates an excellent characteristic in a wide range of several hundred MHz to ten and several GHz.

### Sixth Embodiment

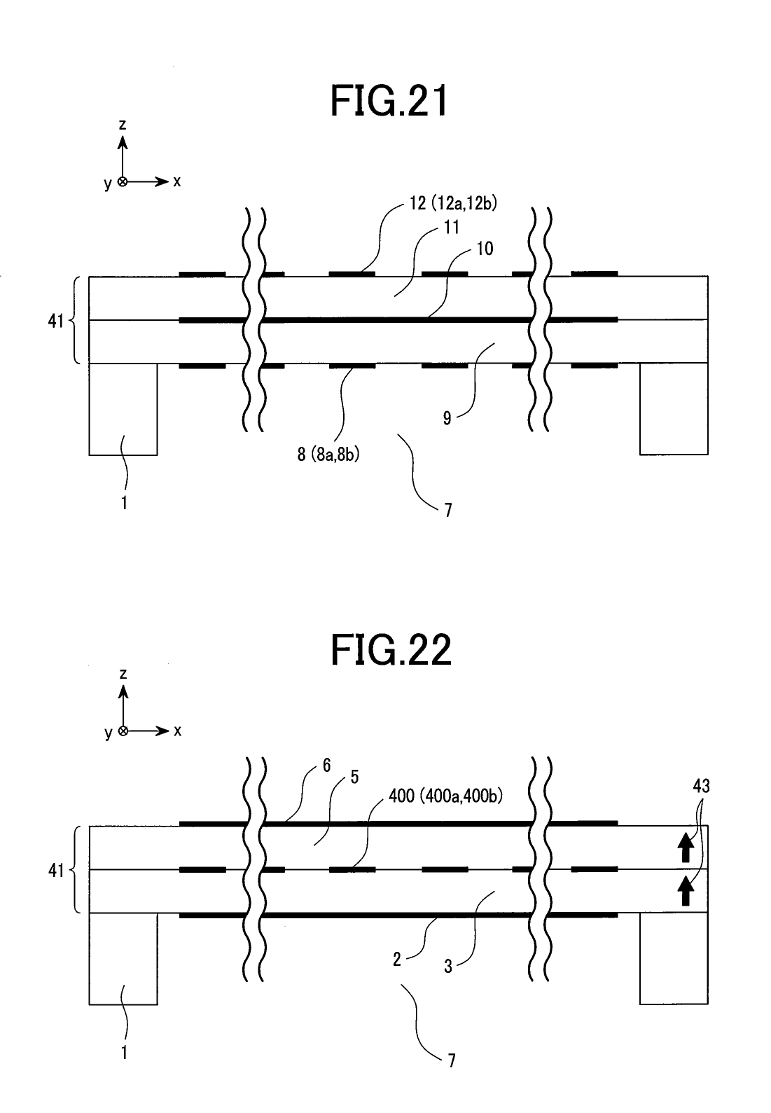

FIG. 21 is a sectional view showing a piezoelectric film resonator according a sixth embodiment of the present invention. The multilayer film 41 including a bottom IDT 8, a bottom piezoelectric layer 9, an intermediate electrode layer 10, a top piezoelectric layer 11, and a top IDT 12 is formed on the substrate 1. The multilayer film 41 is excited by the bottom IDT 8 (8a, 8b) and top IDT 12 (12a, 12b). The intermediate electrode layer 10 is a floating electrode for determining the direction of electric fields so as to increase the electromechanical transduction efficiency. While the electrode fingers of the bottom IDT 8 and those of the top IDT 12 are placed so as to match one another in the z direction relative to the x axis in FIG. 21, they may be placed so as not to match one another in the z direction without being limited by this embodiment.

Also according to this embodiment, properly selecting the thickness h of the multilayer film 41, the period λ₀ of the IDT 12, and the type of wave mode allows the achievement of a piezoelectric film resonator that demonstrates an excellent characteristic in a wide range of several hundred MHz to ten and several GHz.

### Seventh Embodiment

FIG. 22 is a sectional view showing a piezoelectric film resonator according a seventh embodiment of the present invention. As an electrode 400 for excitation instead of the IDT, for example, electrode structures (400a, 400b) in which a plurality of unit patterns each having the place shape of a rectangle are periodically disposed in the x direction may be disposed on the bottom piezoelectric layer. Then positive and negative high frequency power may be alternately applied to the electrode structures 400a and 400b via feeding terminals, or positive and negative high frequency power may be sequentially applied to the electrode structures 400a and 400b at the same time.

Also in this embodiment, the polarization directions of the top and bottom piezoelectric layers are both the z direction. As described above, only antisymmetric mode can selectively be excited because the electric field vectors are inverted in each of the top and bottom piezoelectric layers. This can reduce unnecessary modes that cause a spurious mode.

In the embodiments described above, each multilayer film includes three (top, intermediate, and bottom) electrode layers and top and bottom piezoelectric layers positioned therebetween. However, the multilayer structure of a piezoelectric film resonator according to the present invention is not limited to that of these embodiments. As a matter of course, a multilayer structure in which more electrode layers and/or piezoelectric layers are combined may be adopted.

### Eighth Embodiment

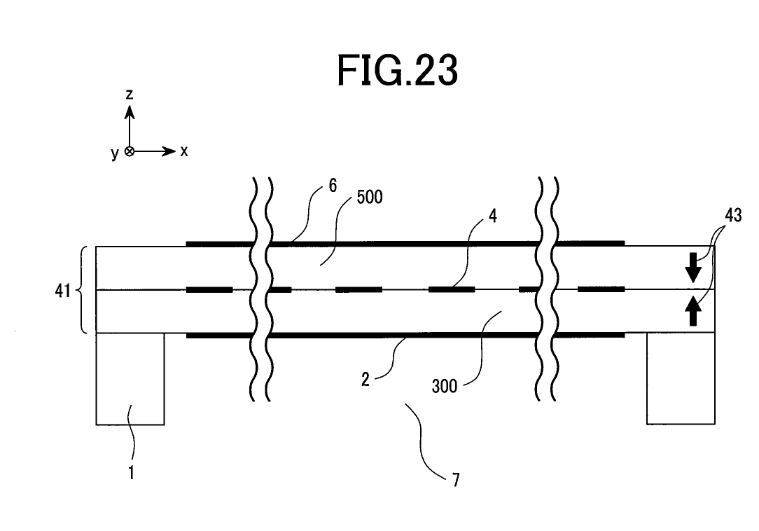

FIG. 23 is a sectional view showing a piezoelectric film resonator according an eighth embodiment of the present invention. The polarization directions of a top piezoelectric layer 500 and a bottom piezoelectric layer 300 are the −z and z directions, respectively. In this embodiment, only symmetric mode can selectively be excited as opposed to the embodiment shown in FIG. 1. This embodiment can also reduce unnecessary modes that cause spurious mode, as with the embodiment shown in FIG. 1.

### Ninth Embodiment

A ninth embodiment, in which a filter using piezoelectric film resonators according to the present invention is disposed on a common substrate, will now be described. In order to manufacture such a piezoelectric film resonator filter, two or more piezoelectric film resonators with different resonant frequencies must electrically be coupled. Two resonance frequencies are sufficient in principle; however, in a wider filter design, three or more resonators with different resonance frequencies may be required.

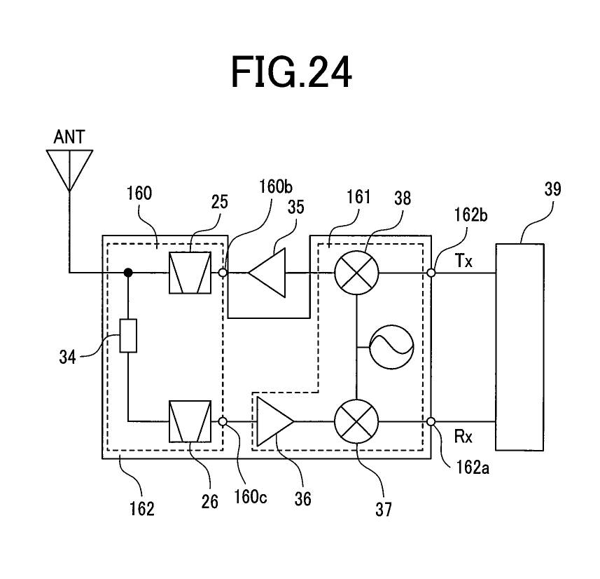

FIG. 24 shows an example of a block circuit diagram of a cellular phone adopting a filter using piezoelectric film resonators according to the invention.

In FIG. 24, a referenced numeral 34 represents a phase shifter that enables an antenna to be shared by a receive part and a transmit part. A radio-frequency reception signal Rx received by an antenna ANT passes through the phase shifter 34 and is inputted into a low noise amplifier 36 via a receive filter 26 for eliminating an image frequency signal from the radio-frequency receive signal Rx and then passing only frequency signals only in a predetermined receive band. The radio-frequency receive signal Rx amplified at the low noise amplifier 36 is transmitted to a baseband part 39 and a cellular phone internal circuit via a receive mixer circuit 37 and an intermediate frequency filter (not shown), and the like.

On the other hand, a transmit signal Tx sent from the baseband part 39 is inputted into a power amplifier 35 via a transmit mixer 38. The transmit signal Tx amplified at the power amplifier 35 is emitted as a radio wave from the antenna ANT via a transmit filter 25 for selectively passing signals in a predetermined transmit frequency band. In the block diagram shown in FIG. 24, a front end part 160 includes the receive filter 26, transmit filter 25, and phase shifter 34.

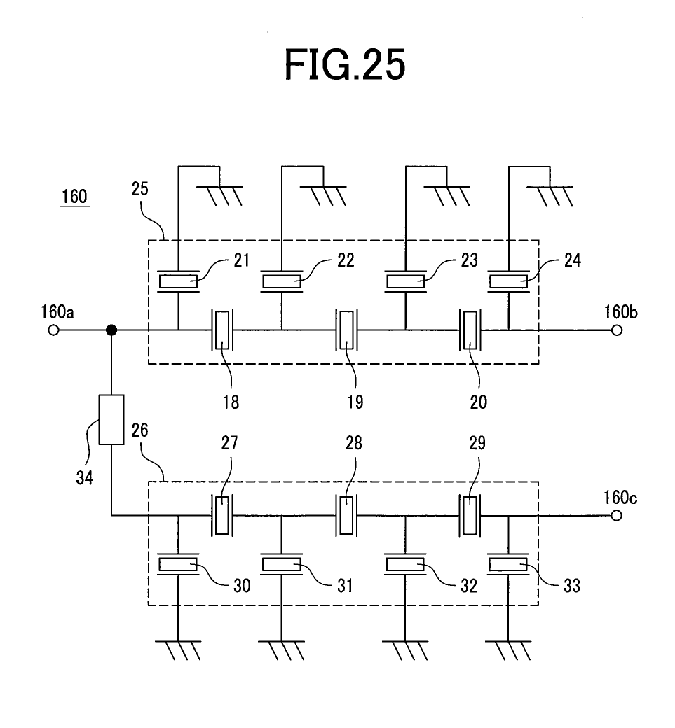

FIG. 25 is an example of the circuit block diagram of the front end part 160 shown in FIG. 24. In FIG. 25, the transmit filter 25 and the receive filter 26 each include an arrangement of a plurality of piezoelectric film resonators according to any one of embodiments of the present invention. The transmit filter 25 includes the arrangement of piezoelectric film resonators 18 to 24 enclosed by a dotted line. The receive filter 26 includes the arrangement of piezoelectric film resonators 27 to 33 enclosed by a dotted line.

A transmit signal is inputted from a terminal 160b coupled to the piezoelectric film resonators 20 and 24 in the transmit filter 25, and outputted from a terminal 160a coupled to the piezoelectric film resonators 18 and 21. On the other hand, a receive signal from the antenna passes through the phase shifter 34, and is inputted into the piezoelectric film resonators 27 and 30 in the receive filter 26 and then outputted from a terminal 160c coupled to the piezoelectric film resonators 29 and 33. In the transmit filter 25, the piezoelectric film resonators 18 to 20 serve as series resonators and the piezoelectric film resonators 21 to 24 serve as parallel resonators. In the receive filter 26, the piezoelectric film resonators 27 to 29 serve as series resonators and the piezoelectric film resonators 30 to 33 serve as parallel resonators.

Note that the arrangement of the piezoelectric film resonators shown here is an example. The arrangement of piezoelectric film resonators depends on the desired filter characteristic, so it is not limited by the arrangement shown in this embodiment. Further, it is possible to manufacture at least one resonator included in a filter using a piezoelectric film resonator according to the present invention and to manufacture other resonators using a known technology such as an FBAR or an SAW device. A circuit used as the phase shifter 34 may include known components such as an inductor and a conductor or a λ/4 transmission line.

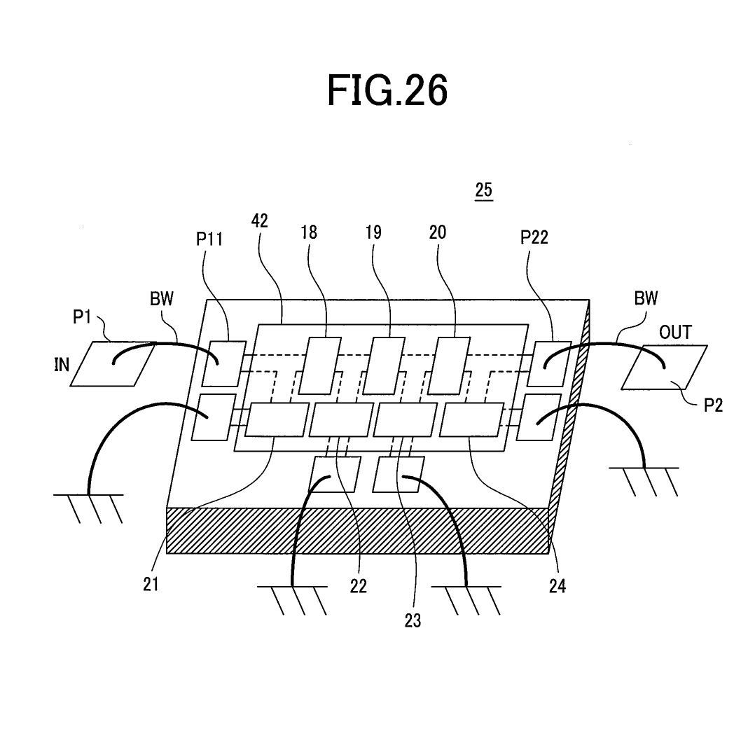

FIG. 26 shows a schematic perspective view when the transmit filter shown in FIG. 25 is manufactured on a common substrate. As the piezoelectric film resonators 18 to 24, piezoelectric film resonators as shown in the first to eighth embodiments described above are used. The piezoelectric film resonators 18 to 20 serve as series resonators and the piezoelectric film resonators 21 to 24 serve as parallel resonators.

In FIG. 26, dotted lines coupling between piezoelectric film resonators represent wires coupling between IDTs. A square region 42 represents a top piezoelectric layer and a bottom piezoelectric layer. A reference numeral P1 represents an input wiring pad through which a transmit signal from an internal circuit (not shown) is transmitted. The input wiring pad P1 is coupled to an filter input pad P11 coupled to the piezoelectric film resonators 18 and 21 in the transmit filter 25 via a bonding wire BW. The input wiring pad P1 is further coupled to a filter output pad 22 via the piezoelectric film resonators 19 and 20 that are coupled to each other in series via electrode wiring. A filter output pad P22 and a pad P2 coupled to an antenna (not shown) are coupled via a bonding wire BW. Wiring pads coupled to the piezoelectric film resonators 21 and 24 are each coupled to a ground pad (not shown) via a bonding wire.

In this way, the transmit filter 25 shown in the circuit diagram of FIG. 25 is formed on the common substrate.

When a filter includes piezoelectric film resonators, the size of the relative bandwidth has a relationship with the width of the frequency passband of the filter. In this embodiment, piezoelectric film resonators according to the invention are used as piezoelectric film resonators in the filter, so the filter can be applied to a radio-communications system with a wide communication band.

While a bonding wire BW is used to couple the internal circuit (not shown) and transmit filter 25 in the embodiment shown in FIG. 26, other implementation methods such as bump bonding may be used.

While a case in which the transmit filter 25 is formed on a common substrate has been described in this embodiment, the receive filter 26 can also be formed on the common substrate. Further, the transmit filter 25 and the receive filter 26, or the front end part 160 including the transmit filter 25 and the receive filter 26 can be formed on the common substrate. This allows the sizes and/or costs of the front end part and a cellular phone including the front end part to be further reduced. In the future, such a front end part can also easily be integrated into a radio-frequency integrated circuit.

### Tenth Embodiment

An RF module using piezoelectric film resonators according to the present invention, which is a tenth embodiment, will now be described. This embodiment is one obtained by modularizing the front end part 160, a radio-frequency circuit part 161, and the low noise amplifier 36 in the block diagram of FIG. 24 as a chipset for a cellular phone. Only the front end part 160 may be modularized. In this case, the front end part 160 is coupled to the radio-frequency circuit part 161 and the low noise amplifier 36 via the terminals 160a and 160b. Alternatively, the front end part 160 and the radio-frequency circuit part 161 may be modularized. In this case, a radio-frequency module 162 is coupled to the baseband part 39 via the terminals 162a and 162b.

Since this embodiment uses a filter using piezoelectric film resonators according to the present invention, an RF module applicable to a radio system with a wide communication band can be provided. Further, modularizing a function of a signal transmit/receive system allows the size and/or cost of a cellular phone including such a module to be reduced.

What is claimed is:

1. A piezoelectric film resonator for a radio-frequency circuit, the piezoelectric film resonator comprising:
a substrate; and
a multilayer film provided on the substrate,
wherein the multilayer film has a stacked structure in which at least two piezoelectric layers and at least three electrode layers disposed with each of the piezoelectric layers therebetween are stacked,
wherein at least one of the electrode layers is an electrode layer for excitation, and
wherein the electrode layer for excitation has a structure in which a plurality of unit patterns as elements of the electrode layer for excitation are disposed periodically along a direction substantially perpendicular to a stacked direction of the stacked structure.

2. The piezoelectric film resonator according to claim 1,
wherein the multilayer film selectively excites only an antisymmetric mode in which a vibration is generated antisymmetrically relative to a center plane of the multilayer film.

3. The piezoelectric film resonator according to claim 1,
wherein the multilayer film selectively excites only a symmetric mode in which a vibration is generated symmetrically relative to a center plane of the multilayer film.

4. The piezoelectric film resonator according to claim 1,
wherein the multilayer film includes:
a bottom electrode layer disposed on the substrate;
a bottom piezoelectric layer disposed on the bottom electrode layer;
an electrode layer for excitation disposed on the bottom piezoelectric layer;
a top piezoelectric layer disposed on the electrode layer for excitation; and
a top electrode layer disposed on the top piezoelectric layer.

5. The piezoelectric film resonator according to claim 1,
wherein the multilayer film includes:
a first electrode layer for excitation disposed on the substrate;
a bottom piezoelectric layer disposed on the first electrode layer for excitation;
an intermediate electrode layer disposed on the bottom piezoelectric layer;
a top piezoelectric layer disposed on the intermediate electrode layer; and
a second electrode layer for excitation disposed on the top piezoelectric layer.

6. A piezoelectric film resonator for a radio-frequency circuit, the piezoelectric film resonator comprising:
a substrate; and
a multilayer film provided on the substrate,
wherein the multilayer film has a stacked structure in which at least two piezoelectric layers and at least three electrode layers disposed with each of the piezoelectric layers therebetween are stacked, and
wherein at least one of the electrode layers is an electrode layer for excitation that includes an interdigital transducer electrode.

7. The piezoelectric film resonator according to claim 6,
wherein at least one of the at least two piezoelectric layers has a polarization direction in parallel to a normal line to a plane of the piezoelectric layer.

8. The piezoelectric film resonator according to claim 6,
wherein a ratio of a thickness h of the multilayer film to a period λ₀ of the electrode layer for excitation is 0.05 or more and 10 or less.

9. The piezoelectric film resonator according to claim 6,
wherein a thickness of the piezoelectric layer is 100 nanometers or more and less than 50 micrometers, and
wherein at least one of the piezoelectric layer is made of a material mainly made of any one of aluminum nitride and zinc oxide.

10. The piezoelectric film resonator according to claim 6,
wherein a resonant frequency to be applied to the electrode layer for excitation is 100 MHz or more, and
wherein the interdigital transducer electrode excites a Lamb wave that is to propagate through the multilayer film.

11. The piezoelectric film resonator according to claim 6,
wherein the electrode layers other than the electrode layer for excitation are floating electrodes, and
wherein each of the other electrode layers is formed as a single plane opposed to entire unit patterns of the electrode layer for excitation.

12. The piezoelectric film resonator according to claim 6,
wherein the substrate has a cavity formed in a region directly below the interdigital transducer electrode.

13. The piezoelectric film resonator according to claim 6, further comprising:
an acoustic isolator layer formed between the substrate and the electrode layer of the multilayer film most adjacent to the substrate.

14. The piezoelectric film resonator according to claim 13,
wherein the acoustic isolator layer is a Bragg reflector layer formed by periodically stacking two or more types of layers with different acoustic impedances.

15. The piezoelectric film resonator according to claim 6, further comprising:
a dielectric layer disposed outside at least one of the electrode layer of the multilayer film remotest from the substrate and the electrode layer of the multilayer film most adjacent to the substrate.

16. The piezoelectric film resonator according to claim 15,
wherein the dielectric layer is made of silicon oxide.

17. A radio-frequency filter, comprising:
a radio-frequency filter circuit; and
a substrate on which the radio-frequency filter circuit is monolithically formed,
wherein the radio-frequency filter circuit comprises:
a plurality of resonators, at least one of which includes a multilayer film provided on the substrate; and
an input terminal and an output terminal coupled to each other via the plurality of resonators,
wherein the multilayer film has a stacked structure in which at least two piezoelectric layers and at least three electrode layers disposed with each of the piezoelectric layers therebetween are stacked,
wherein at least one of the electrode layers is an electrode layer for excitation coupled to the input and output terminals, and
wherein the electrode layer for excitation has a structure in which a plurality of unit patterns as elements of the electrode layer for excitation are disposed periodically along a direction substantially perpendicular to a stacked direction of the stacked structure.

18. A radio-frequency module comprising:
a first terminal;
a first radio-frequency filter whose input terminal is coupled to the first terminal;
a second radio-frequency filter whose output terminal is coupled to the first terminal;
a second terminal coupled to an output terminal of the first radio-frequency filter; and
a third terminal coupled to an input terminal of the second radio-frequency filter,
wherein at least one of the first and second radio-frequency filters is a radio-frequency filter disposed on a first substrate, the radio-frequency filter including:
a plurality of resonators; and
an input terminal and an output terminal coupled to each other via the plurality of resonators,
wherein at least one of the plurality of resonators includes:
a second substrate; and
a multilayer film provided on the second substrate,
wherein the multilayer film has a stacked structure in which at least two piezoelectric layers and at least three electrode layers disposed with each of the piezoelectric layers therebetween are stacked,
wherein at least one of the electrode layers is an electrode layer for excitation, and
wherein the electrode layer for excitation has a structure in which a plurality of unit patterns as elements of the electrode layer for excitation are disposed periodically along a direction substantially perpendicular to a stacked direction of the stacked structure.

19. The radio-frequency module according to claim 18, further comprising:
a fourth terminal; and
a radio-frequency circuit part,
wherein the radio-frequency circuit part is coupled between the second and fourth terminals.

20. The radio-frequency module according to claim 19, further comprising:
a fifth terminal; and
a radio-frequency power amplifier,
wherein an output terminal of the radio-frequency power amplifier is coupled between the third and fifth terminals.
